(19) United States
(12) Patent Application Publication
(10) Pub. No.: US 2024/0152053 A1
(43) Pub. Date: May 9, 2024

(54) METHOD FOR MANUFACTURING SEMICONDUCTOR INTEGRATED CIRCUIT, METHOD FOR MANUFACTURING SEMICONDUCTOR DEVICE, AND EXPOSURE APPARATUS

(71) Applicant: NIKON CORPORATION, Tokyo (JP)

(72) Inventors: Yuho KANAYA, Kumagaya-shi (JP); Soichi OWA, Kumagaya-shi (JP)

(73) Assignee: NIKON CORPORATION, Tokyo (JP)

(21) Appl. No.: 18/268,340

(22) PCT Filed: Dec. 20, 2021
(86) PCT No.: PCT/JP2021/047074

§ 371 Date: Jan. 22, 2024

(30) Foreign Application Priority Data
Dec. 25, 2020 (JP) 2020-217784

(51) Int. Cl. G03F 7/20; H01L 21/027; H01L 21/8234; H01L 27/088

(52) U.S. Cl. CPC G03F 7/20; H01L 21/0274; H01L 21/8234; H01L 27/088

(57) ABSTRACT

A method for manufacturing a semiconductor integrated circuit in each of a plurality of regions on a substrate, the method includes forming an electronic circuit as a part of the semiconductor integrated circuit in each of the plurality of regions by using a mask pattern fixed to a mask substrate, and forming a specific circuit, which expresses specific information specific to each of the semiconductor integrated circuits, on a part of each of the plurality of regions by using a variable shaping exposure apparatus having a variable shaping mask, the specific circuits formed on the plurality of regions being different from each other.

### TECHNICAL FIELD

The present invention relates to a method for manufacturing a semiconductor integrated circuit, a method for manufacturing a semiconductor device, and an exposure apparatus.

Priority is claimed on Japanese Patent Application No. 2020-217784, filed Dec. 25, 2020, the content of which is incorporated herein by reference.

### BACKGROUND ART

In a semiconductor device used for communication, a semiconductor integrated circuit that improves confidentiality of communication by forming a specific circuit that stores a part of specific information in each of a plurality of semiconductor integrated circuits, most of which have a common circuit, has been proposed (Non-Patent Document 1).

### CITATION LIST

### Patent Document

### Non-Patent Document

### [Non-Patent Document 1]

Isabelle Servin, 10 others, “Process development of a maskless N40 via level for security application with multi-beam lithography,” SPIE Proceedings Vol. 10584, SPIE (US), Mar. 19, 2018

### SUMMARY OF INVENTION

According to a first aspect, a method for manufacturing a semiconductor integrated circuit is a method for manufacturing a semiconductor integrated circuit in each of a plurality of regions on a substrate, the method including: forming an electronic circuit as a part of the semiconductor integrated circuit in each of the plurality of regions by using a mask pattern fixed to a mask substrate; and forming a specific circuit, which expresses specific information specific to each of the semiconductor integrated circuits, on a part of each of the plurality of regions by using a variable shaping exposure apparatus having a variable shaping mask, wherein the specific circuits formed on the plurality of regions are different from each other.

According to a second aspect, a method for manufacturing a semiconductor device includes packaging a plurality of semiconductor integrated circuits, which are manufactured by the method for manufacturing a semiconductor integrated circuit according to the first aspect, to provide a plurality of semiconductor devices; and generating second interrelationship data expressing a correspondence between the plurality of packaged semiconductor devices and the specific information expressed by the specific circuit of the semiconductor integrated circuit included in the plurality of semiconductor devices, based on the interrelationship data.

According to a third aspect, an exposure apparatus includes: a substrate holder configured to hold a substrate; a variable shaping mask configured to set a shape of a light and shade pattern which is radiated to the substrate; and a pattern determining part configured to determine a shape of the light and shade pattern exposed to each of a plurality of regions corresponding to a plurality of semiconductor integrated circuits formed on the substrate based on interrelationship data showing a mutual relation between the plurality of semiconductor integrated circuits.

According to a fourth aspect, an exposure apparatus includes a substrate holder configured to hold a substrate; a variable shaping mask configured to set a shape of a light and shade pattern which is radiated to the substrate; and a pattern determining part configured to determine a shape of the light and shade pattern exposed to each of a plurality of predetermined regions corresponding to a plurality of semiconductor integrated circuits to be formed on the substrate based on specific information which is constituted by digital information with a plurality of bits to be formed on each of the plurality of semiconductor integrated circuits.

### BRIEF DESCRIPTION OF DRAWINGS

FIG. 1 is a view schematically showing a plurality of semiconductor integrated circuits manufactured by a method for manufacturing a semiconductor integrated circuit according to a first embodiment.

FIG. 2 is a view showing one of the semiconductor integrated circuits manufactured by the method for manufacturing a semiconductor integrated circuit of the first embodiment.

FIG. 3 is a view showing a circuit diagram of an example of a specific information storage circuit in the semiconductor integrated circuit.

FIG. 4A is an enlarged view of a part of a specific circuit.

FIG. 4B is an enlarged view of a part of the specific circuit.

FIG. 5 is a view for describing a concentration distribution of impurity ions of a part of the specific circuit.

FIG. 6 is a view for describing a flow of the method for manufacturing a semiconductor integrated circuit of the first embodiment.

FIG. 7A is a view for describing a process of forming a partial circuit pattern common to a plurality of semiconductor integrated circuits using a fixed mask.

FIG. 7B is view for describing a process of forming a partial circuit pattern common to the plurality of semiconductor integrated circuits using the fixed mask.

FIG. 8A is a view for describing a process of forming a specific circuit using a variable shaping mask.

FIG. 8B is a view for describing a process of forming the specific circuit using the variable shaping mask.

FIG. 9 is a view for describing a part of a flow of the method for manufacturing a semiconductor integrated circuit.

FIG. 10A is a view for describing an exposure process using the fixed mask and the variable shaping mask.

FIG. 10B is a view for describing an exposure process using the fixed mask and the variable shaping mask.

FIG. 10C is a view for describing an exposure process using the fixed mask and the variable shaping mask.

FIG. 11 is a view showing an example of a method for exposing a substrate in order to form a specific circuit using the variable shaping mask.

FIG. 12 is a view showing summary of interrelationship data showing a mutual relation of a plurality of semiconductor integrated circuits.

FIG. 13 is a view showing summary of an exposure apparatus of a second embodiment.

FIG. 14A is a view showing a summary of a method for manufacturing a semiconductor device of a third embodiment.

FIG. 14B is a view showing a summary of the method for manufacturing a semiconductor device of the third embodiment.

FIG. 15 is a view showing a summary of second interrelationship data showing a mutual relation of a plurality of semiconductor devices.

### DESCRIPTION OF EMBODIMENTS

### Method of Manufacturing Semiconductor Integrated Circuit of First Embodiment

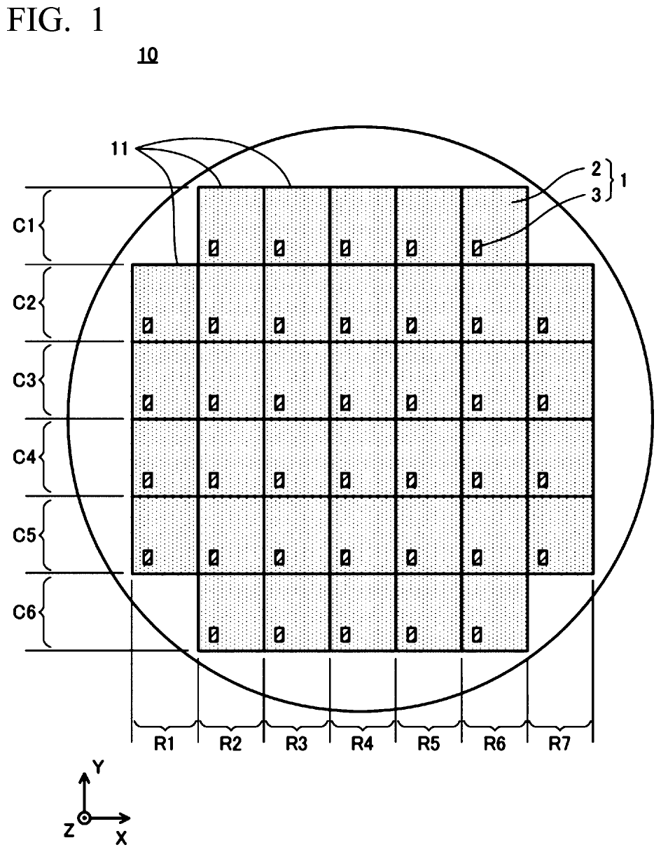

FIG. 1 is a view schematically showing a plurality of semiconductor integrated circuits 1 manufactured on a substrate 10 by a method for manufacturing a semiconductor integrated circuit of a first embodiment.

In FIG. 1 and drawings referenced as below, an X direction, a Y direction and a Z direction shown by arrows are directions perpendicular to each other, and each of the X direction, the Y direction and the Z direction indicates the same direction in each drawing. Hereinafter, the directions indicated by the arrows are referred to as a +X direction, a +Y direction and a +Z direction, respectively. In addition, a position in the X direction is referred to as an X position, a position in the Y direction is referred to as a Y position, and a position in the Z direction is referred to as a Z position.

The method for manufacturing the semiconductor integrated circuit 1 of the first embodiment is provided to manufacture the semiconductor integrated circuit 1 on each of a plurality of regions 11 on the substrate 10 formed of silicon as an example. The plurality of semiconductor integrated circuits 1 formed on the substrate 10 include a common circuit 2 that is an electronic circuit common to each of the semiconductor integrated circuits 1, and a specific circuit 3 that expresses specific information specified for each of the semiconductor integrated circuits 1. In other words, each of the semiconductor integrated circuits 1 includes the common circuit 2 and the specific circuit 3.

As shown in FIG. 1, a shape of the semiconductor integrated circuit 1 in an XY plane is a rectangular shape as an example, and the plurality of semiconductor integrated circuits 1 are disposed two-dimensionally on the substrate 10 in the X direction and the Y direction. Hereinafter, each of the semiconductor integrated circuits 1 may be identified according to an arrangement position thereof using arrangement positions in the X direction as rows (R1 to R7) and arrangement positions in the Y direction as columns (C1 to R6).

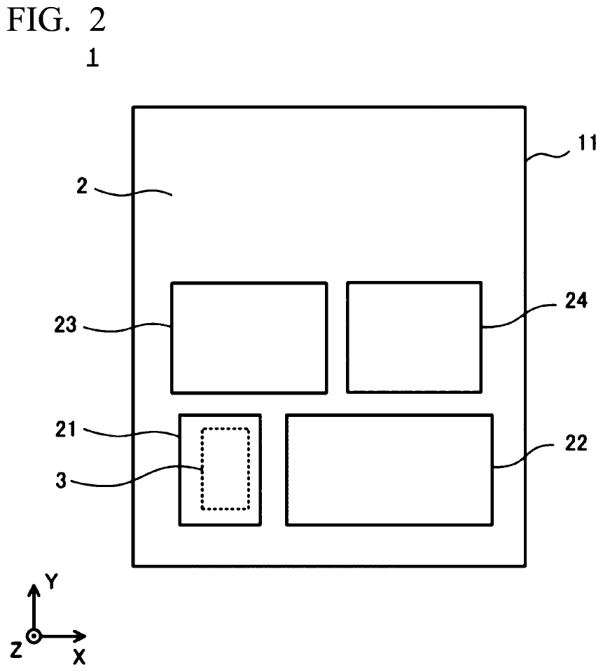

FIG. 2 is an enlarged view showing one of the semiconductor integrated circuits 1 manufactured by the method for manufacturing a semiconductor integrated circuit of the first embodiment. In the semiconductor integrated circuit 1, various types of circuits including an encryption circuit 22, a decryption circuit 23, a communication circuit 24, which will be described below, are formed in a portion of the common circuit 2. A part of a specific information storage circuit 21 is included in the common circuit 2, and the other portion is included in the specific circuit 3 shown by a broken line.

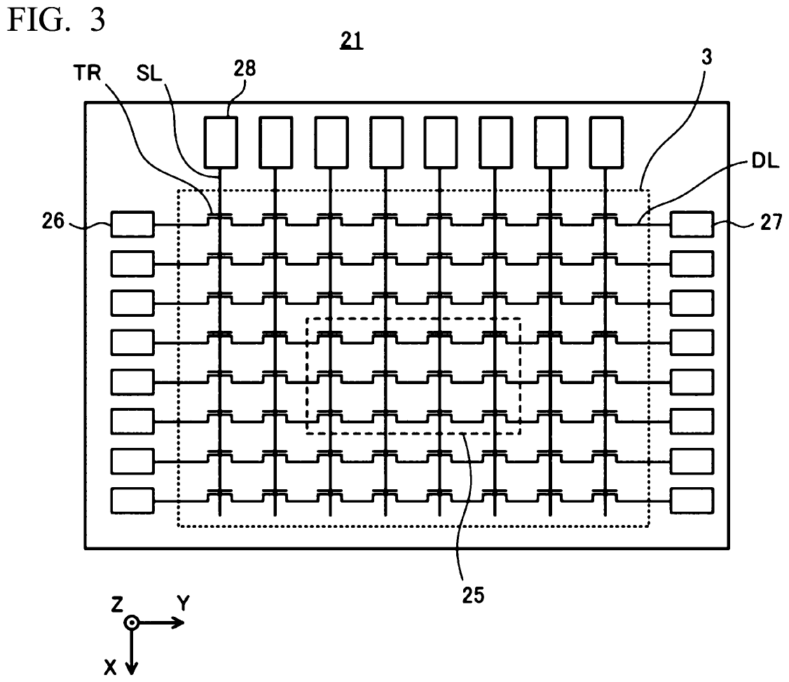

FIG. 3 is a view showing a circuit diagram of an example of the specific information storage circuit 21. The specific information storage circuit 21 is a general NAND type mask ROM circuit as an example, a plurality of MOS transistors TR are disposed along a data line DL extending in the Y direction, and a selection line SL extending in the X direction is connected to a gate of each of the MOS transistors TR. A voltage application unit 26 and a voltage detection unit 27 are disposed on both ends of each of the data lines DL, respectively. A voltage application unit 28 configured to apply a voltage to the gate of each of the MOS transistors TR via the selection line SL is disposed on an end portion of each of the selection lines SL.

In the specific information storage circuit 21, the plurality of MOS transistors TR that constitute a storage region of the mask ROM circuit are included in the specific circuit 3 shown by a broken line. Meanwhile, the voltage application units 26 and 28, and the voltage detection unit 27 are not included in the specific circuit 3, but in the common circuit 2 shown in FIG. 2.

Further, as described above, since the specific information storage circuit 21 is a general mask ROM circuit as a configuration itself, detailed description thereof will be omitted.

Further, in the specification, the circuit includes not only a complete electric circuit that performs one function, but also a part of an electric circuit that has been completed to some extent.

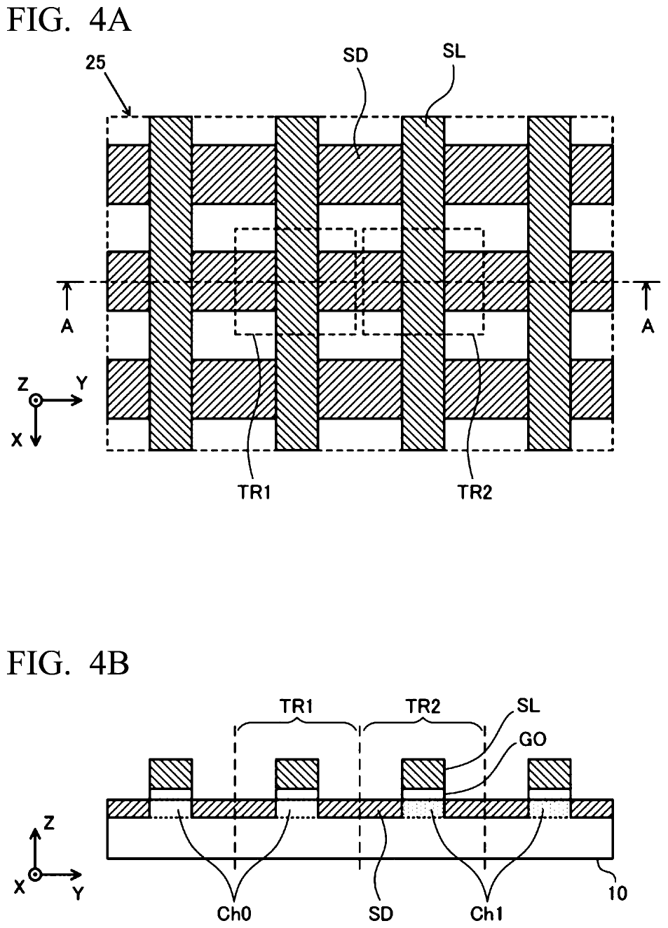

FIG. 4A is a plan view showing a structure of a partial region 25 surrounded by a broken line in FIG. 3 of the specific circuit 3 that is the mask ROM circuit when seen in from the +Z direction. FIG. 4B is a view showing a partial cross section along line AA in FIG. 4A.

The plurality of n type MOS transistors TR (TR1, TR2) constituted by a source/drain region SD, a gate electrode that is the selection line SL, a gate oxide film GO, and channel portions Ch0 and Ch1 as an example are formed in the specific circuit 3. The source/drain region SD is doped with impurity ions that are phosphorus or arsenic at a high concentration as an example.

The source/drain region SD of each of the plurality of MOS transistors TR1 and TR2 disposed at the same X position and arranged in the Y direction is formed continuously in the Y direction. Accordingly, the source/drain region SD and the channel portions Ch0 and Ch1 of the plurality of MOS transistors TR1 and TR2 form the data line DL as a whole (see FIG. 3).

The channel portion Ch0 of some MOS transistors such as the MOS transistors TR1 or the like is considered to be in an intrinsic semiconductor state with a low concentration of impurity ions. Meanwhile, the channel portion Ch1 of some MOS transistors such as the MOS transistors TR2 or the like is, for example, an n-type semiconductor state with a high concentration of impurity ions such as phosphorus and arsenic.

The MOS transistors TR2, which have the channel portion Ch1 with a high concentration of impurity transistors, conduct irrespective of being in a state in which a positive or a 0 [V] electric potential is applied to the selection line SL, which is a gate. Accordingly, the channel portion Ch1 included in the MOS transistors TR2 stores, for example, the state corresponding to data “1.”

Meanwhile, the MOS TR1, which has the channel portion Ch0 with a low concentration of impurity transistors, conducts only in the state where a positive electric potential is applied to the selection line SL, which is a gate. Accordingly, the channel portion Ch0 included in the MOS transistors TR1 stores a state corresponding to, for example, data “0.”

Further, the data stored in the channel portion Ch0 with a low concentration of impurity ions may be “1” and the data stored in the channel portion Ch1 with a high concentration of impurity ions may be “0.”

The plurality of semiconductor integrated circuits 1 formed on the substrate 10 each includes the common circuit 2 and the specific circuit 3. Then, a part of the specific circuit 3, for example, distributions of concentrations of the impurity ions of the channel portions Ch0 and Ch1 are different in the plurality of semiconductor integrated circuits 1.

In the manufacturing method for the first embodiment, in the semiconductor integrated circuit 1, the circuit portion and the common circuit 2 common to the plurality of semiconductor integrated circuits 1 of the specific circuit 3 are formed by exposure using a mask pattern fixed to a mask substrate (hereinafter, the mask substrate and the mask pattern are also collectively referred to as “a fixed mask”). The fixed mask may be, for example, a translucent mask in which a light shielding film such as chromium as a mask pattern or a dielectric substance permeable film as a phase shifter is formed on a translucent mask substrate. Alternatively, it may be a reflective mask in which an absorbent film as a mask pattern or a stepped shape as a phase shifter is formed on a surface of a reflective mask substrate.

Meanwhile, the circuit portions that are different for each of the plurality of semiconductor integrated circuits 1 of the specific circuit 3 are formed by exposure using the variable shaping mask. The variable shaping mask is a so-called spatial light modulator. As the reflective variable shaping mask, for example, the plurality of movable micromirrors may be formed on a reflecting surface, or a reflective liquid crystal display device may be used. As the transmissive variable shaping mask, for example, a transmissive liquid crystal display device may be used. Further, details of the exposure apparatus using the variable shaping mask will be described below.

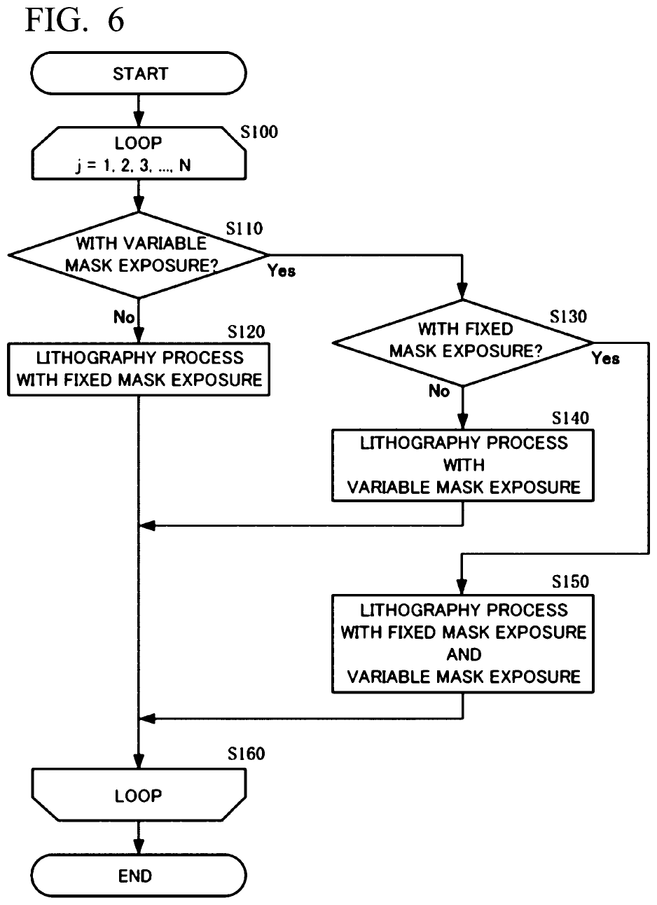

Hereinafter, a flow of the manufacturing method for the first embodiment will be described with reference to FIG. 6.

Like manufacture of a general semiconductor integrated circuit, even in the manufacturing method for the first embodiment, the semiconductor integrated circuit 1 is manufactured by performing a lithography process on the substrate 10 a plurality of times. Accordingly, step S100 is a step of starting a loop including a lithography process N times as a whole.

Further, the substrate 10 is not limited to a single substrate and may be aggregate of a plurality of substrates.

Further, in the specification, the lithography process is a series of processes of forming a photosensitive film (resist) on the substrate 10, patterning a photosensitive film through exposure and development, and processing the substrate 10 using a patterned photosensitive film. The lithography process may include a process of forming a predetermined film on the substrate 10 before forming the photosensitive film. In addition, processing of the substrate 10 may be etching, oxidation, nitration, or ion implantation with respect to the substrate 10 or the predetermined film formed on the substrate 10.

In step S110, a j^{th} lithography process determines whether exposure is performed using a variable shaping mask. In the case in which the determination is negative (No), the process proceeds to step S120, and a lithography process including exposure using a fixed mask is performed. In step S120, the fixed mask on which the circuit pattern that constitutes the common circuit 2 including the encryption circuit 22, the decryption circuit 23, and the communication circuit 24 of the semiconductor integrated circuit 1 is used. Accordingly, in step S120, a circuit pattern that constitutes a part of the common circuit 2 including the encryption circuit 22, the decryption circuit 23, and the communication circuit 24 is formed on the substrate 10.

Since the lithography process including the exposure using the fixed mask is the same as the lithography process normally used for manufacture of the semiconductor integrated circuit, detailed description thereof will be omitted.

Further, the fixed mask used in step S120 may include a mask pattern corresponding to a circuit pattern of the portion common to the plurality of semiconductor integrated circuits 1 of the specific circuit 3. In this case, in step S120, in addition to the various circuit patterns described above, a part of the circuit pattern of the portion common to the plurality of semiconductor integrated circuits 1 of the specific circuit 3 is also formed on the substrate 10.

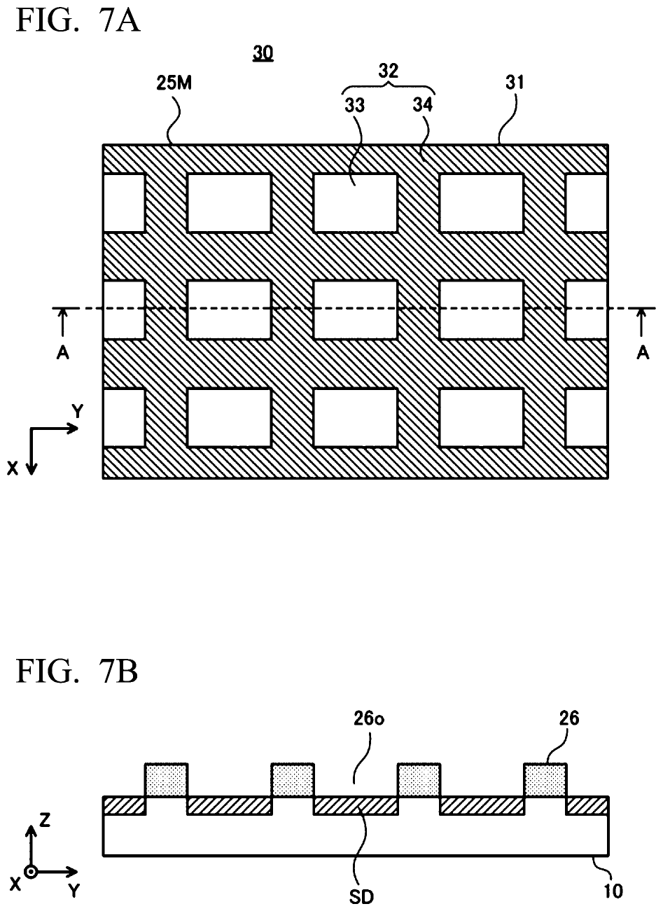

In step S120, the method for forming the circuit pattern of the portion common to the plurality of semiconductor integrated circuits 1 of the specific circuit 3 will be described with reference to FIG. 7A and FIG. 7B. FIG. 7A is a view showing an example of a fixed mask 30 to form the circuit pattern of the portion common to the plurality of semiconductor integrated circuits 1. The fixed mask 30 includes a translucent mask substrate 31, and a mask pattern 32 formed on the surface of the mask substrate 31 and configured to form the source/drain region SD in the specific information storage circuit 21 as an example. The mask pattern 32 includes a transmission portion 33 and a light shielding portion 34.

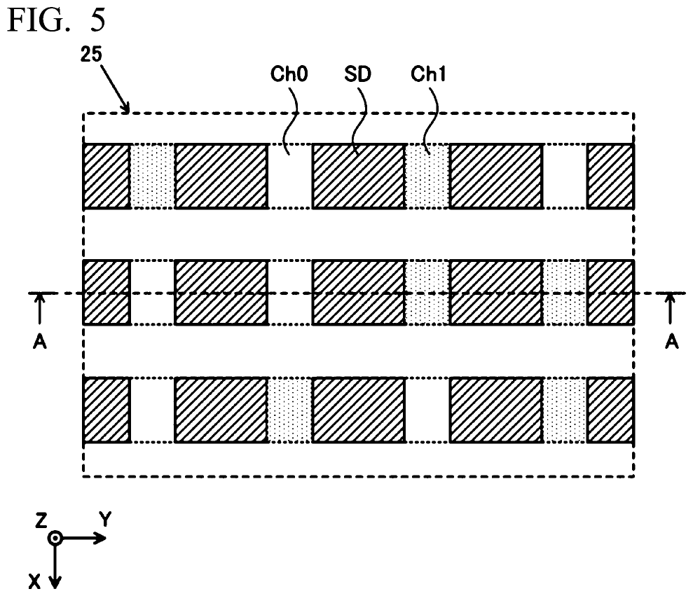

Further, FIG. 7A shows the mask pattern 32 corresponding to a portion 25M equivalent to the partial region 25 shown in FIG. 3 and FIG. 5 of the source/drain region SD in the specific information storage circuit 21. Line AA in FIG. 7A shows a position on the mask pattern 32 corresponding to line AA shown in FIG. 5. Further, the mask pattern 32 may include a portion of the specific information storage circuit 21 other than the partial region 25, and a mask pattern corresponding to other circuits such as the encryption circuit 22, the decryption circuit 23, the communication circuit 24, and the like. Alternatively, the mask pattern 32 does not include a pattern in the partial region 25 of the specific information storage circuit 21 and may include a mask pattern corresponding to other circuits such as the encryption circuit 22, the decryption circuit 23, the communication circuit 24, and the like.

FIG. 7B is view showing a process of forming the source/drain region SD on the portion corresponding to the specific circuit 3 in each of the regions 11 on the substrate 10 using the fixed mask 30 shown in FIG. 7A. FIG. 7B is a cross-sectional view of the substrate 10 along line AA shown in FIG. 5.

First, a photosensitive film 26 such as photoresist or the like is formed on the substrate 10, exposure is performed on the photosensitive film 26 using the fixed mask 30, and the photosensitive film 26 of the portion corresponding to the transmission portion 33 is exposed. Then, the exposed portion of the photosensitive film 26 is removed by development to form an opening portion 26o, and the surface of the substrate is exposed from the opening portion 26o.

After that, arsenic or phosphorus is ion-implanted into the substrate 10 to form the source/drain region SD as an example using the remained photosensitive film 26, i.e., the patterned photosensitive film 26 as a mask.

Further, at the same time, the source/drain region may be formed on the portion other than the partial region 25 of the specific information storage circuit 21, and the predetermined portion in other circuits such as the encryption circuit 22, the decryption circuit 23, the communication circuit 24, and the like.

After termination of the process in step S120, the process proceeds to step S160, and the loop from step S110 to step S160 is repeated until N processes are completed.

In the case in which determination in step S110 is positive (Yes), the process proceeds to step S130. In step S130, the j^{th} lithography process determines whether the exposure is performed using the fixed mask, in addition to the exposure using the variable shaping mask. In the case in which the determination is negative (No), the process proceeds to step S140, and the lithography process including the exposure using the variable shaping mask is performed.

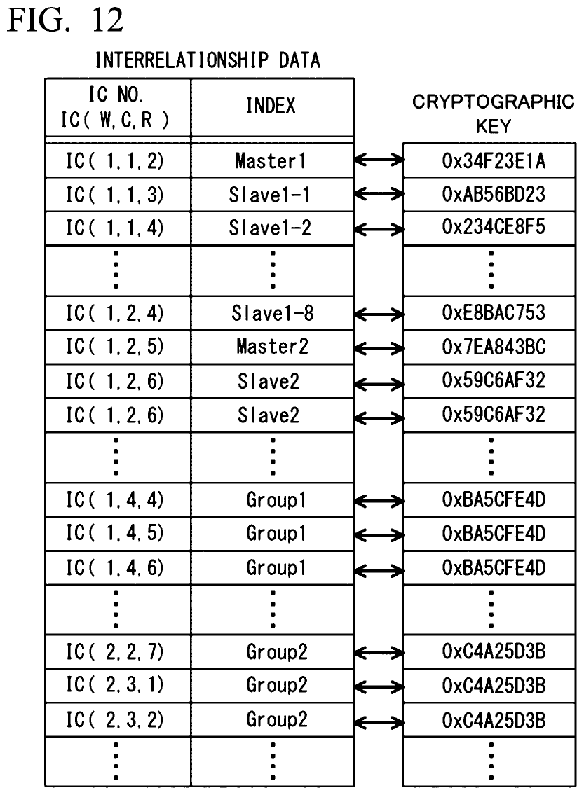

In step S140, for the specific circuit 3 of the specific information storage circuit 21, each of the plurality of semiconductor integrated circuits 1 forms a different circuit pattern. However, as will be described later with reference to FIG. 12, for some of the semiconductor integrated circuits 1, the same pattern may be formed in the specific circuit 3.

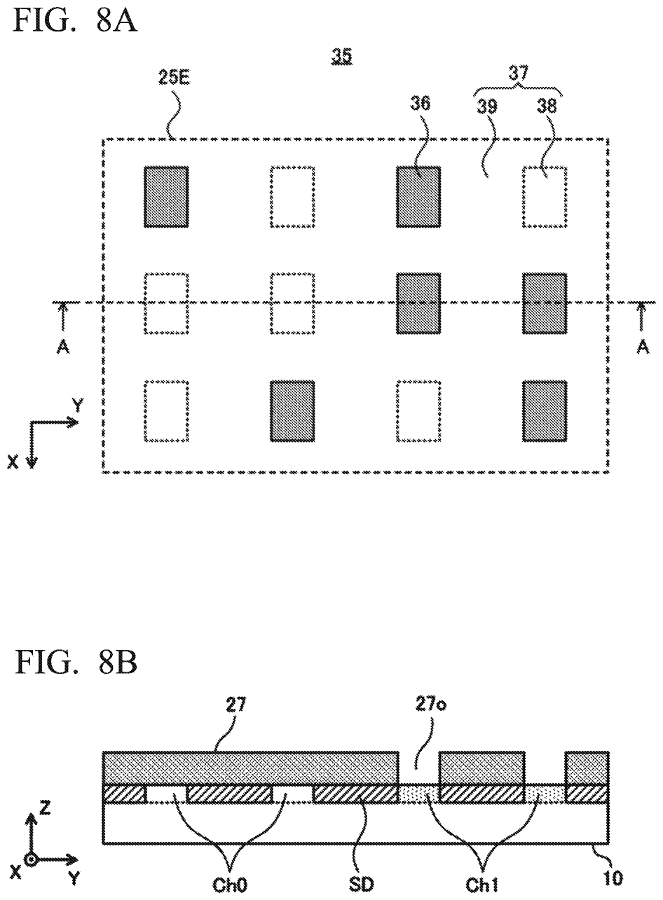

FIG. 8A is a view showing a shape of a light and shade pattern 35 (light and shade distribution) formed on the substrate 10 using the variable shaping mask. Line AA in FIG. 8A shows a position corresponding to line AA shown in FIG. 5. While FIG. 8A shows only the pattern in a small region 25E corresponding to the partial region of the light and shade pattern 35, the light and shade pattern 35 may have an area corresponding to the specific circuit 3 as a whole.

FIG. 8B is a view for describing a method for implanting a predetermined impurity concentration of ions into each of the channel portions Ch0 and Ch1 of the plurality of MOS transistors TR included in the specific circuit 3 using the light and shade pattern 35 shown in FIG. 8A. FIG. 8B is a cross-sectional view of the substrate along line AA shown in FIG. 5.

In step S140, a photosensitive film 27 such as photoresist or the like is formed on the substrate 10, and the light and shade pattern 35 formed on the photosensitive film 27 by the variable shaping mask is exposed. Here, a shape of the light and shade pattern (light and shade distribution) is set such that a portion corresponding to the channel portion Ch1 becomes a bright portion 36, and the other portion becomes a dark portion 37. That is, the variable shaping mask is set such that a portion 38 corresponding to the channel portion Ch0 becomes the dark portion 37 like a portion 39 equivalent to other than the channel portion Ch0 and the channel portion Ch1. The light and shade pattern can be made different for each of the semiconductor integrated circuits 1 formed in the regions 11 in the substrate 10.

The photosensitive film 27 of the portion exposed by the bright portion 36 is removed by subsequent development to become an opening portion 27o, and the surface of the substrate 10 is exposed from the opening portion 27o. After that, arsenic or phosphorus is ion-implanted into the substrate 10 using the remained photosensitive film 27, i.e., the patterned photosensitive film 27 as a mask as an example, and a predetermined concentration of impurity ions are implanted into the channel portion Ch1.

Here, ions are not implanted into the portion corresponding to the channel portion Ch0 because the portion is covered with the photosensitive film 27. Accordingly, the distribution with the predetermined impurity ion concentration can be formed on the channel portion of each of the plurality of MOS transistors that constitute the NAND type mask ROM as an example of the specific information storage circuit 21 by step S140. As described above, for example, 1 bit data “1” is stored in the channel portion Ch1 doped with a high concentration of impurity ions, and 1 bit data “0” is stored in the channel portion Ch0 with which no impurity ion is doped (a low concentration of impurity ions are doped). Accordingly, if the M MOS transistors TR each having the channel portion are provided in the specific circuit 3, M bits information can be stored in the specific circuit 3. The number of the MOS transistors TR included in the specific circuit 3 is not limited to 8×8=64 shown in FIG. 3 and may be an arbitrary number.

Accordingly, different pieces of specific information can be stored in the specific information storage circuit 21 of each of the semiconductor integrated circuits 1 formed in each of the plurality of regions 11 on the substrate 10. In other words, a part of each of the plurality of regions 11 on the substrate 10 can express specific information specific to each of the semiconductor integrated circuits 1, and form the specific circuit 3 in which at least a part of each circuit pattern is different. Further, the concentration distribution of the impurity ions of the channel portions Ch0 and Ch1 described above can also be referred to as a circuit pattern.

After termination of the process in step S140, the process proceeds to step S160, and a loop from step S110 to step S160 is repeated unto N processes are terminated.

When the determination in step S130 is positive (Yes), the process proceeds to step S150.

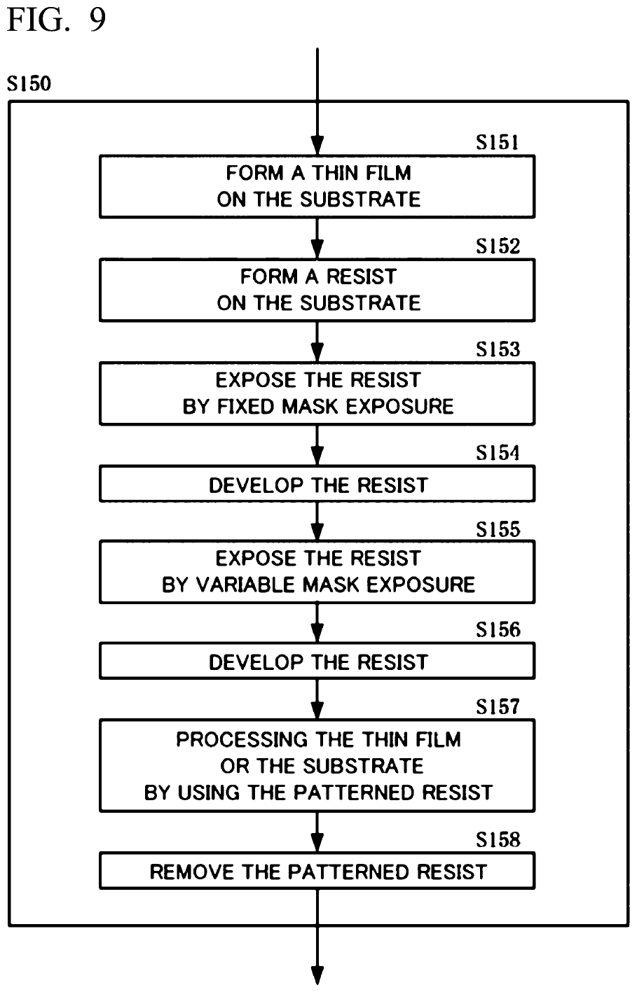

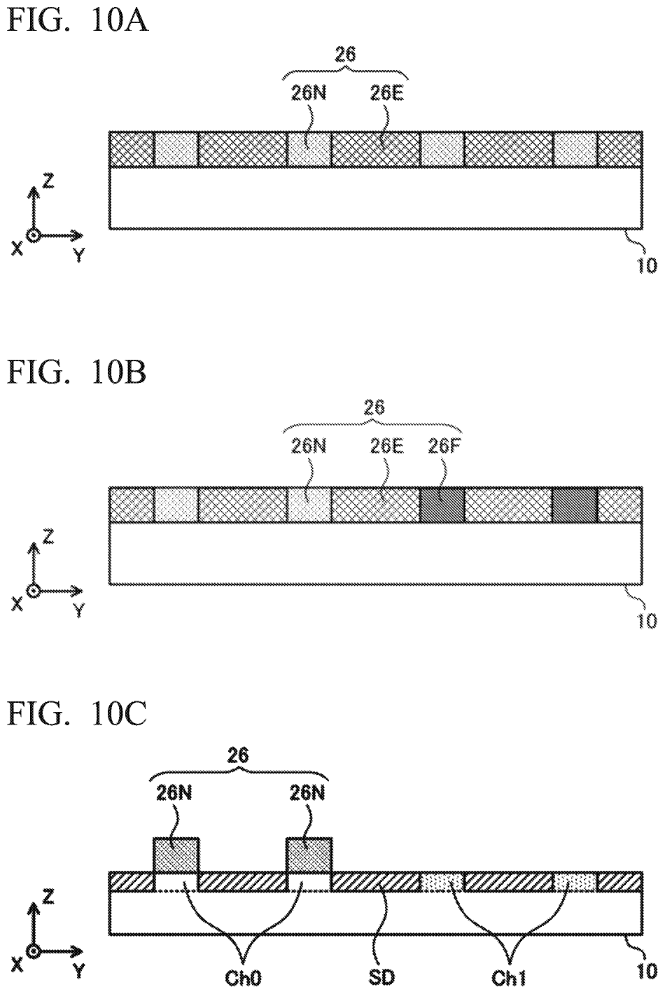

FIG. 9, FIG. 10A, FIG. 10B and FIG. 10C are views for describing the lithography process in step S150, and step S150 is a lithography process of also performing exposure using the variable shaping mask, in addition to the exposure using the fixed mask.

In step S150, as shown in the flow of FIG. 9, a thin film is first formed on the substrate 10 in step S151. Further, when formation of the thin film is not necessary, step S151 may be omitted.

Next, in step S152, the photosensitive film 26 such as photoresist or the like is formed on the substrate 10. Then, in step S153, the photosensitive film 26 is exposed using the fixed mask 30 as shown in FIG. 7A. FIG. 10A shows a cross-sectional view of the substrate 10 and the photosensitive film 26 after the exposure using the fixed mask is performed. Further, like FIG. 7B and FIG. 8B, FIG. 10A is a cross-sectional view of the substrate 10 along line AA in FIG. 5.

An exposure portion 26E is formed on the photosensitive film 26 by the exposure using the fixed mask 30. A portion not exposed by the exposure using the fixed mask 30 remains as a non-exposure portion 26N.

Next, in step S154, the photosensitive film 26 is developed. The photosensitive film 26 after development is in the same state as the photosensitive film 26 shown in FIG. 7B.

After that, in step S155, the light and shade pattern 35 formed on the remained photosensitive film 26 by the variable shaping mask as shown in FIG. 8A is exposed. Then, in step S156, the photosensitive film 26 is developed again. As shown in FIG. 10C, in the photosensitive film 26 after development, only the non-exposure portion 26N exposed by neither the exposure using the fixed mask 30 in step S153 or nor the exposure using the variable shaping mask in step S155 remains on the substrate 10.

In this state, the process proceeds to step S157, and the non-exposure portion 26N shown in FIG. 10C performs processing on the substrate 10 using the remained photosensitive film 26, i.e., the patterned photosensitive film 26. In the example shown in FIG. 10C, the processing on the substrate 10 is ion implantation of arsenic or phosphorus with respect to the substrate 10 as an example, and the source/drain region SD and the channel portion Ch1 are formed by the ion implantation at the same time. Meanwhile, since the channel portion Ch0 is covered with the photosensitive film 26, the ion implantation is not performed.

Further, in step S151, when the thin film is formed on the substrate 10, the ion implantation may be performed not on the substrate 10 but on the thin film formed on the substrate 10.

Further, in the above-mentioned process, when the development of the photosensitive film 26 is performed after the exposure using the fixed mask and the exposure using the variable shaping mask, the development after the exposure using the fixed mask (development in step S154) may be omitted. In this case, in the photosensitive film 26 after execution of step S155, as shown by a cross-sectional view of FIG. 10B, the exposure portion 26E exposed using the fixed mask 30, an exposure portion 26F exposed using the variable shaping mask, and the non-exposure portion 26N, which was not exposed by any exposure, are formed. The photosensitive film 26 (the non-exposure portion 26N) in the state shown in FIG. 10C may be formed by developing the photosensitive film 26 in this state in step S156. In addition, in the above-mentioned process, while the exposure using the variable shaping mask is performed after the exposure using the fixed mask, the exposure using the fixed mask may be performed after the exposure using the variable shaping mask.

As described above, even in step S150, similar to the above-mentioned step S140, a part of each of the plurality of regions 11 on the substrate 10 can express specific information specific to each of the semiconductor integrated circuits 1 using the variable shaping mask, and form the specific circuit 3 having circuit patterns, at least a part of which is different.

After termination of the process in step S150, the process proceeds to step S160, and a loop from step S110 to step S160 is repeated until N processes are terminated.

Further, after termination of step S160, as described below, individual semiconductor integrated circuits 1 may be disconnected (singulated) from the substrate 10.

As shown in FIG. 4A and FIG. 4B, the selection line SL as a gate is formed on the channel portion Ch1 into which ions are implanted and the channel portion Ch0 into which no ion is implanted through the process after that. Accordingly, it is difficult to analyze the concentration of impurity ions in each of the channel portions Ch0 and Ch1 only by observing the completed semiconductor integrated circuit 1 from the upper surface. Accordingly, in the above-mentioned method, it is possible to reduce the risk that the specific information stored in the specific circuit 3 will be reverse-engineered.

Further, in any one of step S120, step S140, and step S150, processing on the substrate 10 using the patterned photosensitive films 26 and 27 is not limited to the above-mentioned ion implantation. That is, the processing on the substrate 10 may be another processing such as etching, oxidation, nitration, or the like, on the substrate 10 or a predetermined film formed on the substrate 10. In addition, after forming a groove or a hole by performing predetermined etching on the substrate 10 or the predetermined film formed on the substrate 10, a conductor such as a metal or the like may be partially embedded in the groove or the hole.

In addition, even in step S120 and step S140, similar to step S150, a process of forming the predetermined film on the substrate 10 may be performed before formation of the photosensitive films 26 and 27 on the substrate 10.

In addition, after the exposure using the fixed mask 30 or the exposure using the variable shaping mask and prior to the development, PEB processing of heating the photosensitive films 26 and 27 may be performed.

Further, the specific circuit 3, which expresses the specific information specific to each of the semiconductor integrated circuits 1 and has at least a part of the circuit patterns different from each other, and the specific information storage circuit 21 including the specific circuit 3 are not limited to the above-mentioned NAND type mask ROM. Accordingly, the pattern specific to each of the semiconductor integrated circuits 1 in the specific circuit 3 is not limited to the above concentration distribution of the impurity ions.

The pattern specific to the semiconductor integrated circuit 1 in the specific circuit 3 may be presence or absence of a specific transistor in the circuit constituting the electronic element, a difference in gate length, or a difference in gate width. Alternatively, it may be the presence or absence or the difference in size of a connecting portion such as a specific via hole in the circuit that constitutes the electronic element. Then, it may be a circuit in which the signal “1” or the signal “0” is stored depending on the difference in the operating characteristics of the electronic element caused by the presence or absence or the difference in size of these.

Formation of the transistor, the via hole, or the like, thereof may be performed by the lithography process including exposure using a variable shaping exposure apparatus two times or more.

Further, in the above-mentioned step S140 and step S150, formation of the channel portions Ch0 and Ch1, which are specific patterns representing the specific information specific to the semiconductor integrated circuit 1 in the specific circuit 3, can be performed by a single lithography process including the exposure using the variable shaping exposure apparatus. Accordingly, the required number of times of exposure using the variable shaping exposure apparatus, which takes longer processing time than the exposure using the fixed mask 30, can be reduced, and the productivity of the semiconductor integrated circuit 1 can be increased.

Further, the exposure using the variable shaping exposure apparatus is not limited to the exposure using the light containing the above-mentioned ultraviolet light, but may be the exposure using a charged particle beam such as an electron beam or the like. In this case, for example, a so-called blanking aperture array may be used as the variable shaping mask.

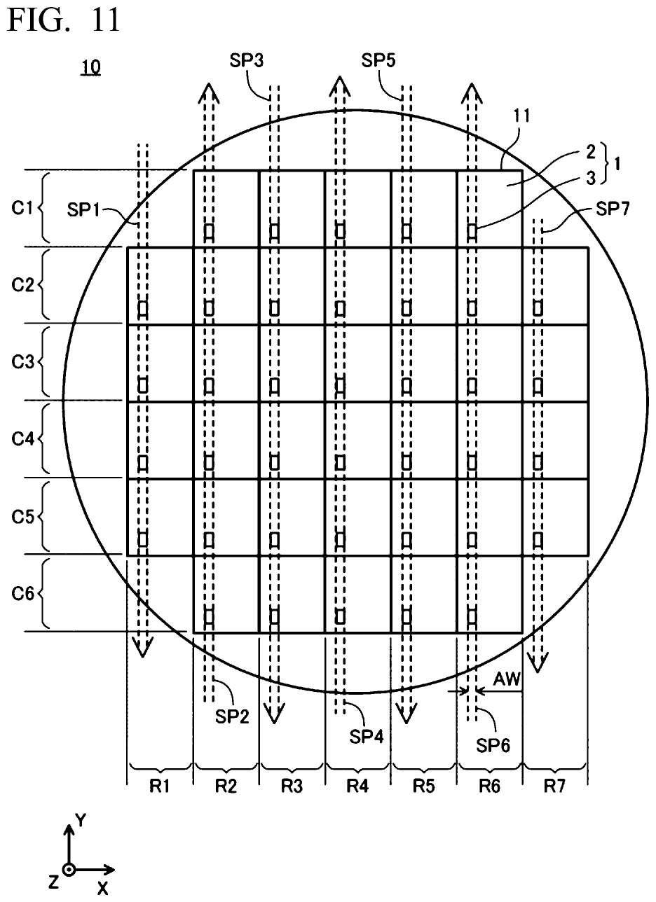

Next, an example of the method for exposing the substrate 10 to the light and shade pattern in order to form the specific circuit 3 using the variable shaping mask will be described with reference to FIG. 11.

As shown in FIG. 1, the plurality of semiconductor integrated circuits 1 are formed in the regions 11 disposed two-dimensionally on the substrate 10 in the X direction and the Y direction, respectively. Accordingly, by arranging the specific circuit 3 at a common position inside each of the semiconductor integrated circuits 1, the plurality of specific circuits 3 are disposed two-dimensionally in the X direction and the Y direction.

Here, as shown in FIG. 11, for example, the plurality of specific circuits 3 may be exposed by a single scanning exposure in the Y direction using the exposure apparatus including the variable shaping mask. That is, the plurality of specific circuits 3 included in the semiconductor integrated circuits 1 of the plurality of regions 11 disposed on a row R1 may be exposed by scanning exposure along a scanning route SP1 shown by a broken line. Similarly, the plurality of specific circuits 3 included in the semiconductor integrated circuits 1 of the plurality of regions 11 disposed in each of the rows R2 to R7 may be exposed by each of the scanning exposures along scanning routes SP2 to SP7.

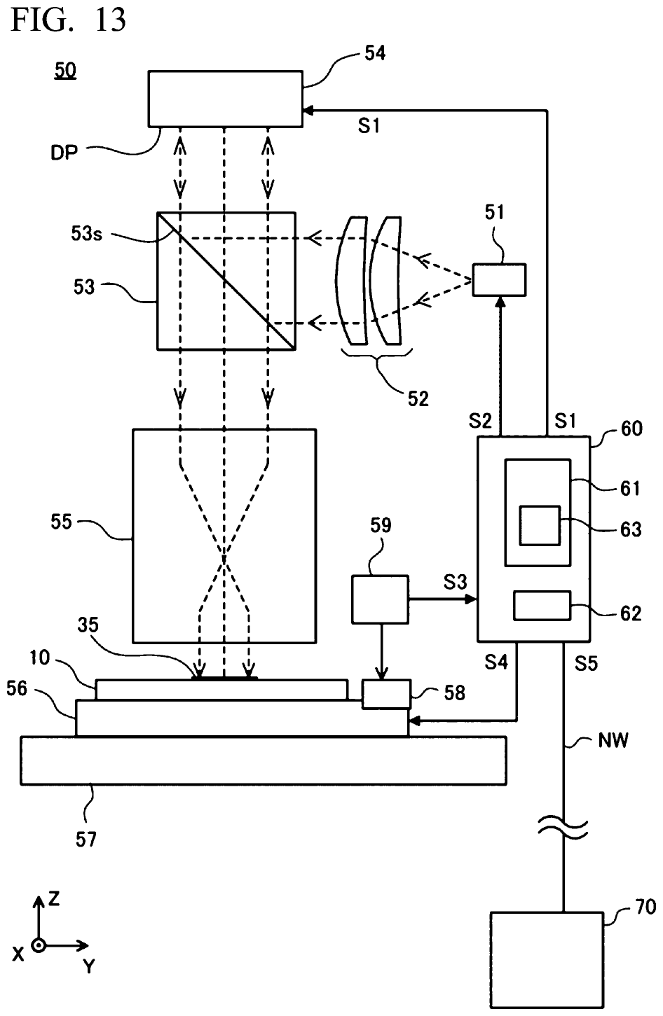

A width AW of the specific circuit 3 in the X direction may be, for example, about 100 μm or less, and therefore, an exposure field of view in the X direction of the exposure apparatus provided with the variable shaping mask may also be about 100 μm or less. The exposure apparatus provided with the variable shaping mask will be described below with reference to FIG. 13.

By performing such scanning exposure, it is possible to reduce the time required to accelerate or decelerate the substrate 10 before and after the exposure of each of the specific circuits 3, thus, the processing time required for exposure can be reduced, and throughput can be improved.

Further, as shown in FIG. 11, in the scanning routes SP1 to SP7 adjacent to each other in the X direction, by mutually reversing the scanning directions (moving directions of the substrate 10 during exposure), a moving distance of the substrate 10 between the scanning routes SP1 to SP7 may be reduced. Accordingly, the throughput may be further improved.

Further, the scanning exposure using the exposure apparatus with the variable shaping mask is not limited to along the Y direction, but may be along the X direction.

The Y direction (or the X direction) may be referred to as the first direction, and the X direction (or the Y direction) may be referred to as the second direction that crosses the Y direction (or the X direction) that is the first direction.

Next, an example in which a cryptographic key is stored in the specific circuit 3 will be described with reference to FIG. 12 as an example of specific information.

The cryptographic key is a cryptographic key used when the encryption circuit 22 encrypts or the decryption circuit 23 decrypts a signal transmitted or received by the semiconductor integrated circuit 1.

As the cryptographic key, for example, a numerical value of a 4-bite hexadecimal code such as 0x34F23E1A or the like is used. Accordingly, the specific circuit 3 in the specific information storage circuit 21 of the semiconductor integrated circuit 1 formed in each of the regions 11 on the substrate 10 stores a cryptographic key with a value according to the use purpose of the semiconductor integrated circuit 1 formed in each of the regions 11.

Which cryptographic key is to be stored in the semiconductor integrated circuit 1 formed in each of the regions 11 is determined based on interrelationship data (INTERRELATIONSHIP DATA) shown in FIG. 12. The interrelationship data is data indicating a mutual relation between one of the plurality of semiconductor integrated circuits 1, which are to be manufactured, and another one or plural ones. In other words, the interrelationship data is data showing a relationship between a substrate No. W of the substrate 10 on which the semiconductor integrated circuit 1 is formed, the arrangement position (column) C in the Y direction on the substrate 10, and another semiconductor integrated circuit 1 of each of the semiconductor integrated circuits 1 specified by the arrangement position (row) R in the X direction. A management number (IC No.) of IC (W, C, R) is applied to the semiconductor integrated circuit 1 disposed at a position of a column C and a row R of the substrate No. W, i.e., a W^{th} substrate.

As an example, in the interrelationship data, a reference sign (INDEX) referred to as a Master-1 showing that there is a the semiconductor integrated circuit 1 to be a master chip in a first set of the plurality of semiconductor integrated circuits 1 is allocated to the semiconductor integrated circuit 1 of a management No. IC (1, 1, 2). According to this, the specific information storage circuit 21 of the semiconductor integrated circuit 1 of the management No. IC (1, 1, 2) stores a cryptographic key 0x34F23E1A that causes it to function as the master chip in the 1^{st} set of the plurality of semiconductor integrated circuits 1.

In addition, reference sign referred to as Slave-1-1 showing that the semiconductor integrated circuit 1 of the management No. IC (1, 1, 3) is the semiconductor integrated circuit 1 to be a 1^{st} slave chip in the 1^{st} set of the plurality of semiconductor integrated circuits 1 is allocated. According to this, the specific information storage circuit 21 of the semiconductor integrated circuit 1 of the management No. IC (1, 1, 3) stores a cryptographic key 0xAB56BD23 that causes it to function as a 1^{st} slave chip in the 1^{st} set of the plurality of semiconductor integrated circuits 1.

Similarly, the semiconductor integrated circuit 1 of the management No. IC (1, 1, 4) stores a cryptographic key 0x7EA843BC that causes it to function as a 2^{nd} slave chip in the 1^{st} set of the plurality of semiconductor integrated circuits 1 so as to correspond to the allocated reference sign referred to as Slave-1-2.

As another example, the semiconductor integrated circuit 1 of the management No. IC (1, 2, 5) stores a cryptographic key 0x7EA843BC that causes it to function as a master chip in a 2^{nd} set of the plurality of semiconductor integrated circuits 1 so as to correspond to the allocated reference sign referred to as Master-2. Then, the semiconductor integrated circuits 1 of the management No. IC (1, 2, 6) and the management No. IC (1, 2, 7) store the same cryptographic key 0x59C6AF32 that causes it to function as a slave chip in the 2^{nd} set of the plurality of semiconductor integrated circuits 1 so as to correspond to the allocated reference sign referred to as Slave-2.

As further another example, the semiconductor integrated circuits 1 of the management No. IC (1, 4, 4), the management No. IC (1, 4, 5), and the management No. IC (1, 4, 6) store a common cryptographic key 0xBA5CFE4D that causes it to function as the plurality of semiconductor integrated circuits 1 belonging to a set referred to as Group-1 so as to correspond to the allocated reference sign referred to as Group-1.

Similarly, the semiconductor integrated circuits 1 of the management No. IC (2, 2, 7), the management No. IC (2, 3, 1), and the management No. IC (2, 3, 2) formed on a 2^{nd} substrate 10 store a common cryptographic key 0xC4A25D3B that cause it to function as the plurality of semiconductor integrated circuits 1 belonging to a set referred to as Group-2 so as to correspond to the allocated reference sign referred to as Group-2. Further, the cryptographic key is not limited to the 4-bite hexadecimal code described above, and may be digital data of arbitrary number of bits. In addition, instead of the cryptographic key itself, for example, it may be digital data obtained as a result of performing a predetermined calculation on the cryptographic key. The cryptographic key itself and the digital data obtained as a result of predetermined calculations on the cryptographic key are hereinafter also referred to as “information related to the cryptographic key.”

The plurality of semiconductor integrated circuits 1 manufactured by the manufacturing method for the first embodiment is capable of communication with encryption and decryption only with one or a plurality of other semiconductor integrated circuits 1 related to each other by the reference sign corresponding to the information related to the cryptographic key stored in each of the specific circuits 3. In other words, by forming the plurality of semiconductor integrated circuits 1 with a generally common circuit pattern and changing a part of the circuit pattern in the specific circuit 3, respectively, it is possible to manufacture the semiconductor integrated circuit 1 capable of communicating with the other specific one or only the plurality of semiconductor integrated circuits 1.

Further, the specific information stored in the specific circuit 3 is not limited to the cryptographic key described above, and for example, may be identification information representing each of the semiconductor integrated circuits 1.

The specific information such as a cryptographic key stored in the specific circuit 3 may be determined by a semiconductor manufacturer that implements the method for manufacturing the semiconductor integrated circuit 1 of the first embodiment. Further, the correspondence between the specific information and each reference sign included in the interrelationship data may also be determined by the semiconductor manufacturer. Alternatively, a consigner who consigns the manufacturing of the semiconductor integrated circuit 1 to the semiconductor manufacturer may determine the above specific information or the correspondence between each specific information and the reference sign.

If the semiconductor manufacturer determines the correspondence between the specific information and the reference sign included in the interrelationship data, or the specific information, only the semiconductor manufacturer will know the specific information actually stored in the semiconductor integrated circuit 1. Accordingly, in this case, since the information related to the specific information is not known to anyone other than the semiconductor manufacturer, it is possible to maintain a high level of confidentiality related to the specific information such as cryptographic keys or the like.

In addition, as described below, the correspondence between the specific information and the reference sign included in the interrelationship data, or the specific information, may be determined (generated) by a variable shaping exposure apparatus used in exposure using a variable shaping mask as described below. In this case, the specific information actually stored in the semiconductor integrated circuit 1 can only be grasped by the variable shaping exposure apparatus, and cannot be known by anyone else. Accordingly, in this case, a higher degree of confidentiality related to the specific information can be maintained.

The interrelationship data may also be generated by a semiconductor manufacturer that implements the method for manufacturing the semiconductor integrated circuit 1 of the first embodiment, or generated by a variable shaping exposure apparatus used in exposure using a variable shaping mask as described later. Alternatively, the interrelationship data may be determined by a consigner who consigns manufacturing of the semiconductor integrated circuit 1 to a semiconductor manufacturer.

When the interrelationship data is generated by the semiconductor manufacturer or the variable shaping exposure apparatus, the interrelationship data may be assigned to a user of the semiconductor integrated circuit 1 (a person who consigns the manufacture of the semiconductor integrated circuit 1) together with the plurality of manufactured semiconductor integrated circuits 1. The user who uses the semiconductor integrated circuit 1 may select and use the semiconductor integrated circuit 1 that matches the purpose of use from among the plurality of semiconductor integrated circuits 1 based on the interrelationship data assigned by the manufacturer.

### Effects of Method for Manufacturing Semiconductor Integrated Circuit of First Embodiment

(1) The method for manufacturing the semiconductor integrated circuit 1 of the first embodiment described above is the method for manufacturing the semiconductor integrated circuit 1 in each of the plurality of regions 11 on the substrate 10, the method including forming the electronic circuit (the common circuit 2) as a part of the semiconductor integrated circuit 1 in each of the plurality of regions 11 by using the mask pattern 32 fixed to the mask substrate 31, and forming the specific circuit 3, which expresses the specific information specific to each of the semiconductor integrated circuits 1, on a part of each of the plurality of regions 11 by using the variable shaping exposure apparatus having the variable shaping mask, the specific circuits 3 formed in the plurality of regions 11 being different from each other.

According to this configuration, the plurality of semiconductor integrated circuits 1 each having the specific circuit 3 can be manufactured at low cost.

(2) The electronic circuit that is the common circuit 2 may include at least a part of the circuit that encrypts or decrypts information (the encryption circuit 22, the decryption circuit 23), and the specific information may be information related to the cryptographic key used when the information is encrypted or decrypted.

According to this configuration, by forming the plurality of semiconductor integrated circuits 1 with a generally common circuit pattern and changing a part of the circuit pattern in the specific circuit 3, respectively, it is possible to manufacture the semiconductor integrated circuit 1 capable of communicating with the other specific one or only the plurality of semiconductor integrated circuits 1.

(3) The electronic circuit (the common circuit 2) may be formed in each of the plurality of the regions which are disposed along a first direction and a second direction crossing the first direction on the substrate 10, and a formation of the specific circuit 3 may include relatively scanning the substrate 10 on which the photosensitive film 26 is formed with respect to the variable shaping exposure apparatus in the first direction (Y direction), and performing exposure during the scanning with respect to the plurality of regions 11 disposed along the first direction (Y direction) among the plurality of regions 11 during scanning.

According to this configuration, the specific circuit 3 can be formed in a shorter time, and the productivity of the semiconductor integrated circuit 1 can be further enhanced.

(4) The formation of the specific pattern (the channel portions Ch0 and Ch1), which is provided in the specific circuit 3 and which expresses the specific information specific to the semiconductor integrated circuit 1, may be performed by a single lithography process including exposure using a variable shaping exposure apparatus. Accordingly, the number of times of exposure using the variable shaping exposure apparatus can be reduced, and the productivity of the semiconductor integrated circuit 1 can be further enhanced.

(5) The electronic circuit (the common circuit 2) may include the NAND type mask ROM (the specific information storage circuit 21), and the specific circuit 3 may include a concentration distribution of impurity ions implanted into the channel portions Ch0 and Ch1 of each of the plurality of MOS transistors TR that constitute the NAND type mask ROM. According to this configuration, the number of times of exposure using the variable shaping exposure apparatus can be reduced, and the productivity of the semiconductor integrated circuit 1 can be further enhanced.

### Exposure Apparatus of Second Embodiment

FIG. 13 is a view schematically showing a configuration of an exposure apparatus 50 of a second embodiment. The exposure apparatus 50 of the second embodiment is a variable shaping exposure apparatus including a variable shaping mask 54 and configured to expose a light and shade pattern 35, a shape of which is deformable, on the substrate 10. The variable shaping mask 54 may be any one of the spatial light modulators mentioned above, but in this embodiment, a reflective spatial light modulator with a plurality of micro reflecting surfaces arranged on a variable mask surface DP is adopted. The exposure apparatus 50 further includes a transmission optical system 52, a branching element 53, an imaging optical system 55, a substrate holder 56, a surface table 57, a controller 60, and the like.

The substrate 10 is placed on the substrate holder 56 disposed on the surface table 57. The substrate 10 is movable on the surface table 57 by the substrate holder 56 in the X direction and the Y direction. In addition, the substrate 10 can also be moved in the Z direction by a micro distance by the substrate holder 56, and can be further rotated (tilted) by a micro angle in the X direction and the Y direction as a rotary shaft.

The position of the substrate 10 in the X direction and the Y direction is measured by a position measurement part 59 via a position of a scale plate 58 provided in the substrate holder 56, and is sent to the controller 60 as a measurement signal S3. The controller 60 sends a position control signal S4 to the substrate holder 56 on the basis of the measurement signal S3 and controls the substrate 10 to be disposed at predetermined X position and Y position.

The controller 60 sends an exposure control signal S2 to a light source 51, and controls light emission timing and a light emission amount of the light source 51.

The exposure apparatus 50 may be a scanning type exposure apparatus that performs exposure while scanning the substrate 10 and the substrate holder 56 relative to a projection optical system 55 in the XY in-plane directions. In this case, the exposure apparatus 50 may shorten a processing time required for exposure of the substrate 10 by performing scanning exposure along the scanning routes SP1 to SP7 shown in FIG. 11.

Alternatively, it may be a step and repeat type exposure apparatus configured to perform exposure in a state in which the substrate 10 and the substrate holder 56 are fixed to the projection optical system 55, and after termination of the exposure, sequentially move the substrate 10 and the substrate holder 56 with respect to the projection optical system 55.

Even in either the scanning type exposure apparatus or the step and repeat type exposure apparatus, the controller 60 may stop the light source 51 from emitting light other than the timing at which the specific circuit 3 is exposed so that the portion of the common circuit 2 on the substrate 10 is not exposed unnecessarily.

A wavelength of the illumination light emitted from the light source 51 is a wavelength of 450 [nm] or less as an example. Further, as an example, the wavelength of the illumination light may be 193 [nm] or less. The light source 51 may be incorporated inside the exposure apparatus 50 or may be disposed outside the exposure apparatus 50. The illumination light may be guided from the light source 51 to the exposure apparatus 50 using a light guide member such as an optical fiber or the like.

The illumination light emitted from the light source 51 is shaped by the transmission optical system 52, enters the branching element 53 such as a beam splitter or the like, is reflected by a branch surface 53s of the branching element 53, and is irradiated to the variable mask surface DP of the variable shaping mask 54. Then, a part of the illumination light is reflected by the plurality of micro reflecting surfaces (not shown) disposed on the variable mask surface DP, enters the branching element 53 again, and passes through the branch surface 53s of the branching element 53 to enter the imaging optical system 55.

The variable shaping mask 54 changes an angle of the reflecting surface of each of a plurality of micro reflecting members (not shown) disposed on the variable mask surface DP, and reflects some of the reflected light in a direction in which the reflected light cannot pass through the imaging optical system 55. Alternatively, the cancel effect of the phase of the light is caused by making the positions in the Z direction of the reflecting surfaces of the plurality of adjacent micro reflecting members different from each other, and the reflected light from the predetermined portion of the variable mask surface DP toward the imaging optical system 55 is dimmed. Accordingly, the light and shade pattern 35 formed by the variable shaping mask 54 is projected to the surface of the substrate 10.

The controller 60 sends a control signal S1 to the variable shaping mask 54, provides a displacement of a predetermined displacement magnitude to a predetermined micro-reflecting member in the variable mask surface DP, and thus, determines a shape (light and shade distribution) of the light and shade pattern 35 on the surface of the substrate 10.

The controller 60 may include a pattern determining part 61, and an interrelationship data generating part 62. In addition, the controller 60 performs communication with an external server 70 installed outside the exposure apparatus 50 via a network line NW.

The pattern determining part 61 determines a shape (light and shade distribution) of the light and shade pattern 35 exposed to the portion of the specific circuit 3 in the plurality of regions 11 corresponding to the plurality of semiconductor integrated circuits 1 formed on the substrate 10 on the basis of the interrelationship data as shown in FIG. 12. Specifically, for example, a reference sign (INDEX) for each of the semiconductor integrated circuits 1 on the substrate 10 is allocated to the interaction data received from the external server 70 as shown in FIG. 12. The pattern determining part 61 determines specific information to be stored in the specific circuit 3 (for example, the numerical value of the cryptographic key consisting of the hexadecimal code described above) based on the reference sign indicated in the interrelationship data. Further, the pattern determining part 61 determines a shape (light and shade distribution) of the light and shade pattern 35 so as to expose and transfer the circuit pattern corresponding to the specific information onto the substrate 10 on the basis of the determined specific information. Then, the controller 60 controls the variable shaping mask 54 with the control signal S1 so that the light and shade pattern 35 determined by the pattern determining part 61 is projected onto the substrate 10.

An example of the shape of the light and shade pattern 35 is the above-mentioned shape (light and shade distribution) shown in FIG. 8A.

Further, when the exposure apparatus 50 is the above-mentioned scanning type exposure apparatus, the variable shaping mask 54 is dynamically controlled so that the light and shade pattern 35 projected onto the substrate 10 moves in the X direction or the Y direction in synchronization with the scanning on the substrate 10.

The pattern determining part 61 may have a storage 63 that stores shape data of the light and shade pattern 35 corresponding to a plurality of pieces of specific information. The pattern determining part 61 may have a storage 63 that stores shape data of the light and shade pattern 35 corresponding to a plurality of pieces of specific information. In this case, the pattern determining part 61 may read one shape data corresponding to the determined specific information from the storage 63 and use it. Accordingly, the shape data of the light and shade pattern 35 can be determined in a short time compared to the case where the shape data of the light and shade pattern 35 is generated each time the specific information is determined.

In addition, the storage 63 of the pattern determining part 61 may store the shape data of the light and shade pattern 35 corresponding to each of the divided specific information obtained by dividing the specific information by the predetermined number of bits (1 to 16 as an example). In this case, the pattern determining part 61 may read the plurality of pieces of shape data corresponding to the determined specific information from the storage 63 and combine the shape data to obtain the shape data of the light and shade pattern 35.

The shape data stored in the storage 63 may be, for example, data representing an image such as bit map data or TIF data, or data generally representing mask data such as GDSII or the like.

In addition, the shape data stored in the storage 63 may be transmitted from the external server 70 or generated by the controller 60.

Further, the exposure apparatus 50 as a variable shaping exposure apparatus is not limited to the exposure apparatus using light including the above-mentioned ultraviolet light, and may be an exposure apparatus using a charged particle beam such as an electron beam or the like. In this case, as the variable shaping mask 54, for example, a transmissive mask having a so-called blanking aperture array may be used.

As described in the method for manufacturing a semiconductor integrated circuit in the first embodiment, the exposure apparatus 50 may include the interrelationship data generating part 62 for generating the interrelationship data shown in FIG. 12. In this case, the exposure apparatus 50 determines the specific information to be stored in the specific circuit 3 (for example, the numerical value of the cryptographic key consisting of the hexadecimal code described above) based on the self-generated interaction data.

### Effects of Exposure Apparatus of Second Embodiment

(6) The exposure apparatus 50 of the second embodiment includes the substrate holder 56 configured to hold the substrate 10, the variable shaping mask 54 configured to set a shape of the light and shade pattern 35 which is radiated to the substrate 10, and the pattern determining part 61 configured to determine a shape of the light and shade pattern exposed to each of the plurality of regions 11 corresponding to the plurality of semiconductor integrated circuits 1 formed on the substrate 10, based on the interrelationship data expressing a mutual relation between the plurality of semiconductor integrated circuits 1.

According to this configuration, the plurality of semiconductor integrated circuits 1 each having the specific circuit 3 can be manufactured at low cost.

(7) The pattern determining part 61 may determine specific information to be formed on each of the plurality of predetermined regions 11 based on the interrelationship data, and may determine the shape of the light and shade pattern 35 based on the determined specific information.

According to this configuration, for each of the plurality of semiconductor integrated circuits 1, the specific circuit 3 in which separate pieces of specific information is stored can be flexibly formed.

(8) The pattern determining part 61 may include the storage 63 configured to store shape data of the light and shade pattern 35 corresponding to each of the plurality of pieces of specific information, and the pattern determining part 61 may read the shape data corresponding to the determined specific information from the storage 63.

Accordingly, the shape data of the light and shade pattern 35 can be determined in a shorter time.

### Exposure Apparatus of Variant

In the exposure apparatus 50 of the above-mentioned second embodiment, the pattern determining part 61 determines the shape of the light and shade pattern 35 exposed to each of the specific circuits 3 in the plurality of regions 11 based on the interrelationship data expressing mutual relation between the plurality of semiconductor integrated circuits 1.

In the exposure apparatus of the variant, the pattern determining part 61 determines the shape of the light and shade pattern 35 to be exposed to each of the specific circuits 3 based on the specific information consisting of digital information of a plurality of bits to be stored in the specific circuit 3 (for example, the numerical value of the cryptographic key consisting of the hexadecimal code described above).

However, even in the exposure apparatus of the variant, since this configuration is the same as the exposure apparatus 50 of the second embodiment described above, detailed description of the exposure apparatus of the variant will be omitted.

The specific information to be stored in the specific circuit 3 may be received from the external server 70 via the network line NW.

Further, even in the exposure apparatus of the variant, the pattern determining part 61 may have the storage 63 configured to store the shape data of the light and shade pattern 35 corresponding to each of the plurality of pieces of specific information.

Then, the pattern determining part 61 can read one shape data corresponding to the predetermined specific information from the storage 63 and use it.

### Effects of Exposure Apparatus of Variant

(9) The exposure apparatus 50 of the variant includes the substrate holder 56 configured to hold the substrate 10, the variable shaping mask 54 configured to set a shape of the light and shade pattern 35 which is radiated to the substrate 10, and the pattern determining part 61 configured to determine a shape of the light and shade pattern 35 exposed to each of the plurality of predetermined regions 11 corresponding to the plurality of semiconductor integrated circuits 1 to be formed on the substrate 10 based on the specific information which is constituted by digital information with a plurality of bits to be formed on each of the plurality of semiconductor integrated circuits.

According to this configuration, the plurality of semiconductor integrated circuits 1 each having the specific circuit 3 can be manufactured at low cost.

(10) The pattern determining part 61 may have the storage 63 configured to store shape data of the light and shade pattern 35 corresponding to each of the plurality of pieces of specific information. Accordingly, the shape data of the light and shade pattern 35 can be determined in a shorter time.

### Method of Manufacturing Semiconductor Device of Third Embodiment

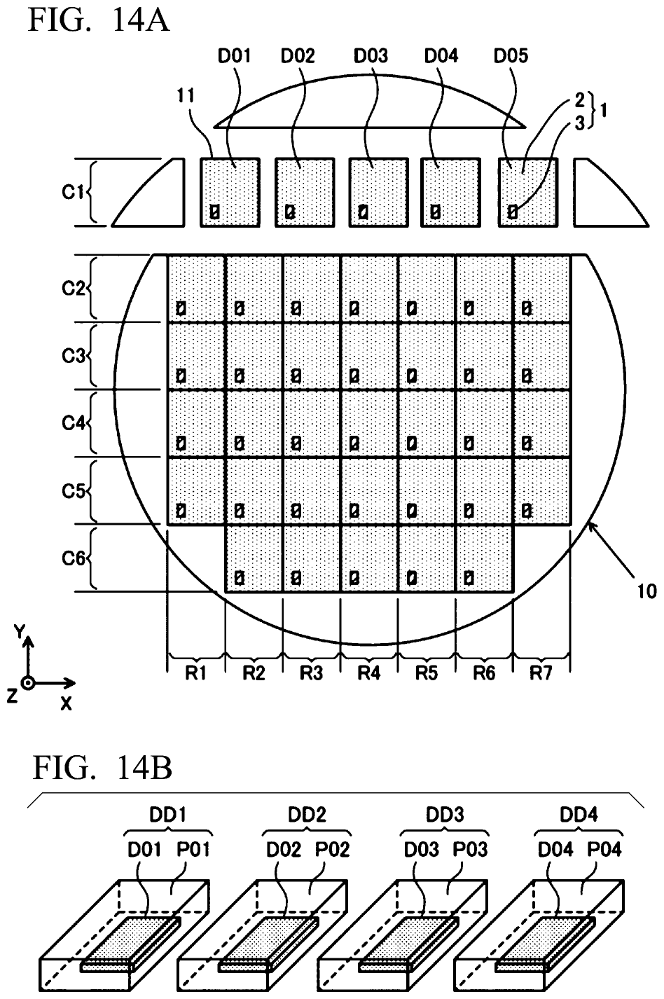

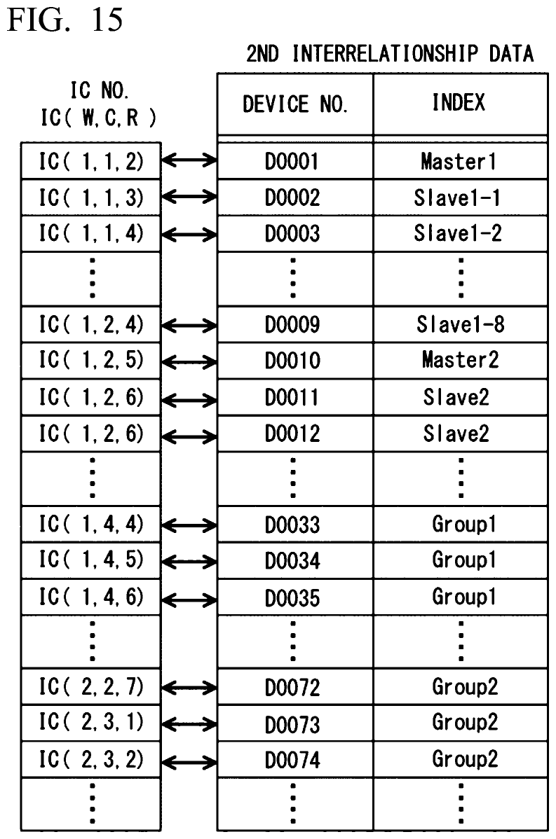

A method for manufacturing a semiconductor device of a third embodiment will be described with reference to FIG. 14A, FIG. 14B and FIG. 15.

The method for manufacturing a semiconductor device of the third embodiment is to package the semiconductor integrated circuit 1 manufactured by the method for manufacturing a semiconductor integrated circuit of the first embodiment into a plurality of semiconductor devices DD1 to DD4. Then, further, second interrelationship data indicating correspondence between the plurality of packaged semiconductor devices DD1 to DD4 and the specific information expressed by the specific circuit 3 of the semiconductor integrated circuit 1 included in each of them is generated on the basis of the interrelationship data shown in FIG. 12.

FIG. 14A is a view for describing a process of cutting the substrate 10 on which the semiconductor integrated circuit 1 manufactured by the method for manufacturing a semiconductor integrated circuit of the first embodiment for each of the semiconductor integrated circuits 1. FIG. 14A shows a state in which the five semiconductor integrated circuits 1 disposed in the column C1 are cut (individualized) from the substrate 10. Hereinafter, the individualized semiconductor integrated circuits 1 are also referred to as semiconductor chips D01 to D05.

Then, as shown in FIG. 14B, the individualized semiconductor chips DOJ to D04 are packaged with packaging members P01 to P04 to complete the semiconductor devices DD1 to DD4, respectively. Any method may be used for a method for packaging the semiconductor chips D01 to D04.

As described in the method for manufacturing a semiconductor integrated circuit of the above-mentioned first embodiment, the management No. IC (W, C, R) constituted by the substrate No. W of the substrate, the arrangement position (column) C on the substrate 10 in the Y direction, and the arrangement position (row) R in the X direction is applied to the semiconductor integrated circuit 1 of the substrate 10. Then, the characteristics of each of the semiconductor integrated circuits 1 defined by the management No. IC (W, C, R) are defined by the interrelationship data (INTERRELATIONSHIP DATA) shown in FIG. 12.

However, when the semiconductor integrated circuits 1 are separated into individual pieces, it is difficult to manage the semiconductor integrated circuits 1 individualized according to this interrelationship data. Here, second interrelationship data indicating the correspondence between the plurality of packaged semiconductor devices DD1 to DD4 and the specific information expressed by the specific circuit 3 of the semiconductor integrated circuit 1 included in the plurality of semiconductor devices DD1 to DD4 is generated based on the interrelationship data.

FIG. 15 is a view showing an example of second interrelationship data (2ND INTERRELATIONSHIP DATA). The second interrelationship data expresses correspondence between the device numbers (DEVICE NOs.) of the plurality of semiconductor devices DD1 to DD4, and the reference sign (INDEX) corresponding to specific information expressed by the specific circuit 3 of the semiconductor integrated circuit 1 included in the semiconductor devices DD1 to DD4 of the device numbers.

The management number (IC No.) shown at a left end of FIG. 15 is a management number allocated to each of the semiconductor integrated circuits 1 on the substrate 10 in the interrelationship data shown in FIG. 12. Like the example shown in FIG. 15, in the second interrelationship data, the management number (IC No.) of the semiconductor integrated circuit 1 in the interrelationship data shown in FIG. 12 may be substituted with device numbers D0001, D0002, and the like, of the semiconductor devices DD1 to DD4 including the semiconductor integrated circuit 1.

The reference sign (INDEX) in the second interrelationship data may be the same as the reference sign in the interrelationship data shown in FIG. 12. Alternatively, the reference sign in the second interrelationship data has the same meaning as the reference sign in the interrelationship data shown in FIG. 12, but may be a different reference sign. For example, when the reference sign in the interrelationship data is “Master1,” the reference sign in the second interrelationship data may be “M1.”

When the semiconductor integrated circuits 1 are packaged as the semiconductor devices DD1 to DD4, the device numbers D0001, D0002, etc. may be stamped on the surfaces of the packaging members P01 to P04, or on the surfaces of the semiconductor integrated circuits 1 that are not covered by the packaging members P01 to P04.

The manufacturer of the semiconductor devices DD1 to DD4 assigns the second interrelationship data to the purchaser together with the semiconductor devices DD1 to DD4 when assigning the semiconductor devices DD1 to DD4. A user who uses the semiconductor devices DD1 to DD4 may select the semiconductor devices DD1 to DD4 that match the purpose of use from among the plurality of semiconductor devices DD1 to DD4 and use them on the basis of the second interrelationship data assigned by the manufacturer. Accordingly, it is possible to easily manage the plurality of semiconductor devices DD1 to DD4.

### Effects of Method for Manufacturing Semiconductor Device of Third Embodiment

(11) The method for manufacturing the semiconductor devices DD1 to DD4 of the above-mentioned third embodiment includes packaging each of the plurality of semiconductor integrated circuits 1, which are manufactured by the method for manufacturing a semiconductor integrated circuit of the above-mentioned first embodiment, to provide the plurality of semiconductor devices DD1 to DD4, and generating the second interrelationship data expressing correspondence between the plurality of packaged semiconductor devices DD1 to DD4 and the specific information expressed by the specific circuit 3 of the semiconductor integrated circuit 1 included in the plurality of semiconductor devices DD1 to DD4, based on the interrelationship data.

According to this configuration, the plurality of semiconductor devices DD1 to DD4 including the semiconductor integrated circuits 1 each having the specific circuit 3 can be manufactured at low cost, and management of the plurality of the semiconductor devices DD1 to DD4 can be facilitated.

Although the various embodiments and variants have been described above, the present invention is not limited to these contents. In addition, each of the embodiments and variants may be applied individually or in combination. Other aspects conceivable within the scope of the technical spirit of the present invention are also included without departing from the scope of the present invention.

### REFERENCE SIGNS LIST

DD1 to DD4 Semiconductor device
1 Semiconductor integrated circuit
2 Common circuit
3 Specific circuit
10 Substrate
11 Region
21 Specific information storage circuit
22 Encryption circuit
23 Decryption circuit
24 Communication circuit
25 Partial region
26, 27 Photosensitive film
TR MOS transistor
Ch0, Ch1 Channel portion
SD Source/drain region
30 Fixed mask
31 Mask substrate
32 Mask pattern
35 Light and shade pattern
SL Selection line
50 Variable shaping exposure apparatus (exposure apparatus)
54 Variable shaping mask
56 Substrate holder
60 Controller
61 Pattern determining part
62 Interrelationship data generating part
63 Storage
70 External server

1. A method for manufacturing a semiconductor integrated circuit in each of a plurality of regions on a substrate, the method comprising:
forming an electronic circuit as a part of the semiconductor integrated circuit in each of the plurality of regions by using a mask pattern fixed to a mask substrate; and
forming a specific circuit, which expresses specific information specific to each of the semiconductor integrated circuits, on a part of each of the plurality of regions by using a variable shaping exposure apparatus having a variable shaping mask,
wherein the specific circuits formed on the plurality of regions are different from each other.

2. The method for manufacturing a semiconductor integrated circuit according to claim 1,
wherein the electronic circuit includes at least a part of a circuit configured to encrypt or decrypt information, and
wherein the specific information is information related to a cryptographic key used when the information is encrypted or decrypted.

3. The method for manufacturing a semiconductor integrated circuit according to claim 1,
wherein the electronic circuit is formed on each of the plurality of regions which are disposed along a first direction and a second direction crossing the first direction on the substrate, and
wherein a formation of the specific circuit includes relatively scanning the substrate on which a photosensitive film is formed with respect to a projection optical system of the variable shaping exposure apparatus in the first direction so as to expose the plurality of regions disposed along the first direction among the plurality of regions, the projection optical system projecting a pattern formed by the variable shaping mask.

4. The method for manufacturing a semiconductor integrated circuit according to claim 1, wherein a formation of the specific pattern, which is provided in the specific circuit and which expresses specific information specific to the semiconductor integrated circuit, is performed by a single lithography process including exposure using the variable shaping exposure apparatus.

5. The method for manufacturing a semiconductor integrated circuit according to claim 1,
wherein the electronic circuit includes a NAND type mask ROM, and
wherein the specific circuit includes a concentration distribution of impurity ions in a channel portion of each of a plurality of MOS transistors that constitute the NAND type mask ROM.

6. The method for manufacturing a semiconductor integrated circuit according to claim 1, comprising:
generating interrelationship data expressing a mutual relation between at least one of the plurality of semiconductor integrated circuits to be manufactured and at least one of the plurality of semiconductor integrated circuits; and
determining a shape of a specific pattern, which expresses specific information formed on the specific circuit of each of the plurality of semiconductor integrated circuits, based on the interrelationship data.

7. The method for manufacturing a semiconductor integrated circuit according to claim 6, wherein the specific information is generated by the variable shaping exposure apparatus.

8. The method for manufacturing a semiconductor integrated circuit according to claim 7, wherein the interrelationship data is generated by the variable shaping exposure apparatus.

9. A method for manufacturing a semiconductor device comprising:
packaging a plurality of semiconductor integrated circuits, which are manufactured by the method for manufacturing a semiconductor integrated circuit according to claim 6, to provide a plurality of semiconductor devices; and
generating second interrelationship data expressing correspondence between the plurality of packaged semiconductor devices and the specific information expressed by the specific circuit of the semiconductor integrated circuit included in the plurality of semiconductor devices, based on the interrelationship data.

10. An exposure apparatus comprising:
a substrate holder configured to hold a substrate;
a variable shaping mask configured to set a shape of a light and shade pattern which is radiated to the substrate; and
a pattern determining part configured to determine a shape of the light and shade pattern exposed to each of a plurality of regions corresponding to a plurality of semiconductor integrated circuits formed on the substrate, based on interrelationship data showing a mutual relation between the plurality of semiconductor integrated circuits.

11. The exposure apparatus according to claim 10, wherein the pattern determining part determines specific information to be formed on each of a plurality of predetermined regions based on the interrelationship data and determines the shape of the light and shade pattern based on the determined specific information.

12. The exposure apparatus according to claim 11, wherein the pattern determining part determines correspondence between the specific information and the interrelationship data.

13. The exposure apparatus according to claim 12, wherein the pattern determining part does not output the specific information to outside.

14. The exposure apparatus according to claim 11, wherein the pattern determining part includes a storage configured to store shape data of the light and shade pattern corresponding to each of plurality of pieces of specific information, and
wherein the pattern determining part reads the shape data corresponding to the determined specific information from the storage.

15. The exposure apparatus according to claim 10, further comprising an interrelationship data generating part configured to generate the interrelationship data.

16. An exposure apparatus comprising:
a substrate holder configured to hold a substrate;
a variable shaping mask configured to set a shape of a light and shade pattern which is radiated to the substrate; and
a pattern determining part configured to determine a shape of the light and shade pattern exposed to each of a plurality of predetermined regions corresponding to a plurality of semiconductor integrated circuits to be formed on the substrate based on specific information which is constituted by digital information with a plurality of bits to be formed on each of the plurality of semiconductor integrated circuits.

17. The exposure apparatus according to claim 16, wherein the pattern determining part includes a storage configured to store shape data of the light and shade pattern corresponding to each of the plurality of pieces of specific information.

18. The exposure apparatus according to claim 17, wherein the pattern determining part generates the specific information.

19. The exposure apparatus according to claim 18, wherein the pattern determining part does not output the specific information to outside.

20. The exposure apparatus according to claim 10,
wherein the substrate holder moves in a first direction and a second direction crossing the first direction along a surface of the substrate, and
wherein, while moving the substrate holder in the first direction, the light and shade pattern is radiated to each of a part in the plurality of predetermined regions arranged discretely in the first direction on the substrate.

21. The exposure apparatus according to claim 20, wherein each of the part in the plurality of predetermined regions are discrete in the second direction.

22. The exposure apparatus according to claim 16, wherein the substrate holder moves in a first direction and a second direction crossing the first direction along a surface of the substrate, and
wherein, while moving the substrate holder in the first direction, the light and shade pattern is radiated to each of a part in the plurality of predetermined regions arranged discretely in the first direction on the substrate.

23. The exposure apparatus according to claim 22, wherein each of the part in the plurality of predetermined regions are discrete in the second direction.

24. A method for manufacturing a device, comprising:
determining a shape of the light and shade pattern by using the pattern determining part according to claim 10,
forming a predetermined exposure pattern on the substrate with exposure light via the variable shaping mask by setting the shape of the light and shade pattern with the variable shaping mask, and
processing a surface of the substrate by using the predetermined exposure pattern formed on the substrate as a mask.

25. A method for manufacturing a device, comprising:
determining a shape of the light and shade pattern by using the pattern determining part according to claim 16,
forming a predetermined exposure pattern on the substrate with exposure light via the variable shaping mask by setting the shape of the light and shade pattern with the variable shaping mask, and
processing a surface of the substrate by using the predetermined exposure pattern formed on the substrate as a mask.
